(19) United States
(12) Patent Application Publication
(10) Pub. No.: US 2015/0129133 A1
(43) Pub. Date: May 14, 2015

(54) PLASMA DEVICE

(71) Applicants: Kee Won SUH, Suwon-si (KR); ALLIED TECHFINDERS CO., LTD., Suwon-si (KR)

(72) Inventor: Kee Won SUH, Suwon-si (KR)

(73) Assignees: ALLIED TECHFINDERS CO., LTD., Suwon-si (KR); Kee Won SUH, Suwon-si (KR)

(21) Appl. No.: 14/539,185

(22) Filed: Nov. 12, 2014

(30) Foreign Application Priority Data
Nov. 12, 2013 (KR) 10-2013-0136639

(51) Int. Cl. H01J 37/32; C23C 16/505

(52) U.S. Cl. CPC H01J 37/3211; C23C 16/505; H01J 2237/334; H01J 2237/3321
USPC 156/345.48; 156/345.1; 118/723 R; 118/723 I

(57) ABSTRACT

The plasma device is disclosed, the plasma device including a chamber configured to accommodate a substrate, and a plasma source formed at one side of the chamber to excite a reaction gas of the substrate introduced into the chamber in a plasma state, wherein the plasma source moves in parallel with the substrate, whereby the substrate can be uniformly plasma-processed.

### CROSS REFERENCE TO RELATED APPLICATION(S)

Pursuant to 35 U.S.C. §119 (a), this application claims the benefit of earlier filing date and right of priority to Korean Patent Application No. 10-2013-0136639, filed on Nov. 12, 2013, the contents of which are hereby incorporated by reference in their entirety.

### BACKGROUND OF THE DISCLOSURE

1. Field

The teachings in accordance with the exemplary embodiments of this present disclosure generally relate to a plasma device configured to process wafer and glass substrate for LCD using plasma devices such as etching or ashing device, and PECVD (Plasma Enhance Chemical Vapor Deposition) and HDPCVD (High Density Plasma CVD) devices.

2. Background

Various plasma sources are known for achieving stringent plasma process requirements, but typical plasma generating sources used for semiconductor wafer manufacturing have developed to, or may be classified into a CCP (Capacitively Coupled Plasma) source of parallel planar surface plasma type, and an ICP (Inductively Coupled Plasma) source employing an antenna coil that couples RF (Radio Frequency) energy into a working gas in a vacuum chamber.

The former has been developed by TEL (Tokyo Electron) of Japan, and the latter has been developed by LRC (Lam Research) of USA, and the latter is being further developed by AMT (Applied Materials) and LRC of USA.

As a line spacing pitch becomes fine, the method employing an antenna coil suffers from some intrinsic problems and limitations and is gradually ruled out. However, the antenna coil-employing method has re-surfaced as one of important methods due to the trend of fine line spacing pitch, although the method suffers from disadvantages such as, for example, gas pressure ranges being typically limited to low pressures, problems with plasma uniformity and wafer edge region prone to severe non-uniformity, albeit excellent plasma density.

In case of small sized glass substrate for LCD, although the small sized glass substrate for LCD has been processes using plasma, uniform plasma had not been generated as the glass substrate grows larger. As a result, AMT of USA, TEL of Japan, ADP Engineering and JuSung Engineering of Korea manufacture deposition devices or etching devices by generating capacitively coupled Plasma of parallel planar type.

While the CCP (Capacitively Coupled Plasma) method may be advantageous in generating uniform plasma, the CCP method is disadvantageous because wafer or glass substrate, which is a processed article, is directly affected by electromagnetic field to inflict damage to fine pattern formation of the processed article. On top of that, the CCP source has a density relatively lower than that of ICP source to make the line spacing pitch narrower when processing the wafer to the disadvantage of pattern formation.

Furthermore, a high power may be applied to a broader region (7th generation and 8th generation) when processing a glass substrate to make it difficult to transfer a uniform power to electrodes and to provide a greater damage to the processed article and to the device due to high power. To wrap up, the CCP source method is disadvantageous because manufacturing cost rises and there are many difficulties in manufacturing the processed articles.

### SUMMARY OF THE DISCLOSURE

The present disclosure is to provide a plasma device configured to uniformly plasma-process a substrate.

It should be emphasized, however, that the present disclosure is not limited to a particular disclosure, as explained above. It should be understood that other technical subjects not mentioned herein may be appreciated by those skilled in the art.

In one general aspect of the present disclosure, there is provided a plasma device, the plasma device comprising:

a chamber configured to accommodate a substrate; and

a plasma source formed at one side of the chamber to excite a reaction gas of the substrate introduced into the chamber in a plasma state, wherein the plasma source moves in parallel with the substrate.

Preferably, but not necessarily, the plasma source may move to a wire or to a belt.

Preferably, but not necessarily, the plasma source may include an antenna coil connected to an RF power source, and a mover configured to translate the antenna coil, and the mover includes a ball screw or a cam configured to transform a rotational motion of a motor to a translational motion.

Preferably, but not necessarily, the plasma source may include an antenna coil connected to an RF power source, and a mover configured to translate the antenna coil, wherein the mover includes a ball screw or a cam configured to transform a rotational motion of a motor to a translational motion, and wherein the ball screw is connected to the motor, and the motor and the ball screw are rotated to one direction of a forward direction or a backward direction, and wherein at least one of the ball screw and the cam is formed with the motor rotating to the said one direction and a first guide configured to transform a rotational motion of the ball screw to a direct motion of the cam, and wherein the first guide is formed with a trajectory configured to move the cam to the other direction of the ball screw after moving the cam to one direction of the ball screw.

Preferably, but not necessarily, the plasma source may include an antenna coil connected to an RF power source, and a mover configured to translate the antenna coil, wherein the mover includes a cam part, and wherein the cam part takes a cylindrical shape externally formed with a first guide in a graph shape of periodic function, and wherein the antenna coil is connected to the cam part or to a second guide moving along the first guide.

Preferably, but not necessarily, the first guide may include a first section to allow the second guide to cruise, and a second section extended from the first section to reduce speed, and wherein the second section includes an acceleration section in which the second guide accelerates after finish of the speed reduction, and wherein the speed of the second guide at the acceleration section is faster than the second guide at the first section.

Preferably, but not necessarily, the plasma source may include an antenna coil connected to an RF power source, and a mover configured to translate the antenna coil, wherein a plurality of covers is arranged between the chamber and the antenna coil, and wherein each cover is arranged along a first direction when the antenna coil moves in parallel to the first direction.

Preferably, but not necessarily, the plasma source may include an antenna coil connected to an RF power source, and a mover configured to translate the antenna coil, wherein the mover moves along the first direction and the antenna coil is extended to a second direction which is different from the first direction.

Preferably, but not necessarily, the antenna coil may be formed with a U-shape to allow an average voltage to be constantly applied along a direction distancing from the mover with the mover as a starting point.

### ADVANTAGEOUS EFFECTS OF THE DISCLOSURE

The plasma device according to the exemplary embodiment of the present disclosure has an advantageous effect in that a surface of a substrate can be uniformly plasma-processed by moving a plasma source configured to excite a reaction gas of the substrate to a plasma state in parallel to the substrate.

### BRIEF DESCRIPTION OF DRAWINGS

FIG. 1 is a schematic cross-sectional view illustrating a plasma device according to the present disclosure.

FIG. 2 is a plan view illustrating a plasma source constituting a plasma device according to the present disclosure.

FIG. 3 is a schematic view illustrating a cam part constituting a plasma device according to the present disclosure.

FIG. 4 is a schematic view illustrating a mover applied with a cam part.

FIG. 5 is a schematic view illustrating another plasma device according to the present disclosure.

FIG. 6 is a schematic view illustrating another cam part constituting a plasma device according to the present disclosure.

### DETAILED DESCRIPTION OF THE DISCLOSURE

Hereinafter, exemplary embodiments of the present disclosure will be described in detail with reference to the accompanying drawings. In describing the present disclosure, certain layers, sizes, shapes, components or features may be exaggerated for clarity and convenience. Accordingly, the meaning of specific terms or words used in the specification and claims should not be limited to the literal or commonly employed sense, but should be construed or may be different in accordance with the intention of a user or an operator and customary usages. Therefore, the definition of the specific terms or words should be based on the contents across the specification.

A plasma source according to the present disclosure is a large sized plasma source (200) suitable for processing of a substrate (10) having a round, a polygonal shape and other shapes, easy in extendibility relative to size, and particularly appropriate for semiconductor fabricating process using a substrate (10). The plasma source according to the present disclosure is an ICP (Inductively-Coupled Plasma) source configured to independently generate plasma employing etching or ashing device, and PECVD (Plasma Enhance Chemical Vapor Deposition) and HDPCVD (High Density Plasma CVD) devices, or any suitable processes known in the art and/or combinations thereof.

Furthermore, the plasma source according to the present disclosure is easy in extendibility free from size of region, and may be useful for manufacturing process of glass substrate for LCD, and CNT (Carbon Nano Tube). An RF power inputted from a harmonic power source (RF power source) to one electrode through an impedance matcher is connected to parallel-connected two or more antenna coils (210). The antenna coil (210) generates plasma by parallel motion relative to the substrate (10).

The present disclosure relates to an ICP source (200) configured to lengthen a length of an antenna in response to size of a substrate (10) of processed article, and to be easily transform a geometric shape of the antenna coil (210), and can provide a plasma source (200) arranged at an upper surface of a deposition device or an etching device.

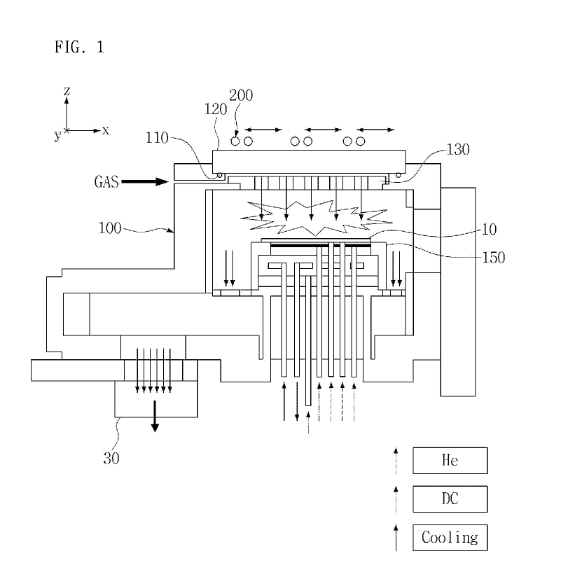

FIG. 1 is a schematic cross-sectional view illustrating a plasma device according to the present disclosure.

Referring to FIG. 1, a plasma device according to the present disclosure includes a chamber (100) and a plasma source (200). The chamber (100) may be formed with an interior space for accommodating a substrate (10). An interior of the chamber (100) may be provided with a chuck unit (150) mounted with the substrate (10). The chuck unit (150) may be provided with an RF power source, a DC power source, a line supplied by a cooling gas. The RF power source connected to the chuck unit (150) may generate plasma inside the chamber (100) by cooperating with the RF power source supplied to the plasma source (200). The DC power source may apply to the chuck unit (150) a polarity inducing the reaction gas excited to plasma state to move a direction facing the substrate (10). The cooling water is provided to cool the chuck unit (150).

The chuck unit (150) may cool the substrate (10) by being discharged to an interior of the chamber (100) through a hole provided at the chuck unit (150). The chamber (100) may be provided at an upper surface with an antenna coil (210) as a plasma source (200).

A pump (30) may be connected to a bottom surface of the chamber (100) to make the interior of the chamber (100) vacuum. An upper surface of the chamber (100) is disposed with an O-ring (110) to seal the chamber (100) using a cover (120). The cover (120) is preferably quartz glass plate. The interior of the chamber (100) may be arranged with the substrate (10) and a gas plate (130) for uniformly supplying the reaction gas.

The reaction gas at the upper surface of the chamber (100) may be excited to a plasma state by the plasma source (200).

The plasma source (200) may be formed at one side of the chamber (100) to excite the reaction gas introduced into the chamber (100) to a plasma state. The plasma source (200) may include the antenna coil (210) applied with the RF power source. The harmonic power source (RF power source) may be applied to the antenna coil (210) via an impedance matcher, for example. An inductive electromagnetic field generated by the antenna coil (210) forms plasma by being excited inside the chamber (100) via the cover (120) formed with the quartz glass plate, where the substrate (10) placed on a substrate pedestal is processed by the plasma. At this time, the RF power source may be from several hundred KHz to several hundred MHz.

The antenna coil (210) may be arranged at an upper surface of the chamber (100), and may be formed within a scope to cover the upper surface of the chamber (100) for evenly form the plasma inside the chamber (100). However, despite the abovementioned structure, the plasma generated from the plasma source (200) is not uniformly distributed inside the chamber (100). Resultantly, the substrate (10) accommodated inside the chamber (100) has a limit in being evenly plasma- processed. In order to cope with the disadvantage, the present disclosure proposes a plasma source (200) that moves in parallel relative to the substrate (10).

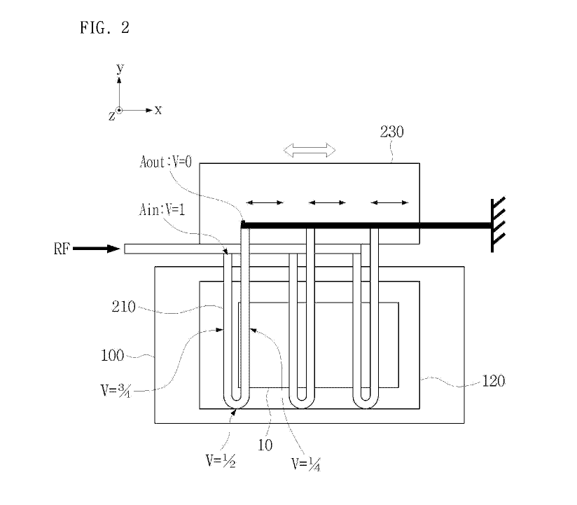

FIG. 2 is a plan view illustrating a plasma source constituting a plasma device according to the present disclosure.

When the plasma source (200) and the substrate (10) are arranged at mutually different positions on z axis phase in a xyz 3-D (dimensional) space, the plasma source (200) may include one or more antenna coils (210) arranged on the xy plane. When the substrate (10) is arranged on xy plane, the antenna coil (210) may move along x axis or y axis on a position facing the substrate (10). The antenna coil (210) under this configuration may move in parallel to the substrate (10).

It should be apparent that the intensity (strength) of plasma decreases as distanced from the antenna coil (210). Thus, there is generated a difference in plasma density applied to the substrate (10), but according to the configuration of the present disclosure where plasma source moves in parallel to the substrate (10), the plasma can be uniformly provided to the substrate (10).

In order to further uniformly perform the plasma-processing to the substrate (10), the plasma source (200) may perform a reciprocating movement relative to the substrate (10). That is, the plasma source (200) may translate relative to the substrate (10). At this time, the uniformity of plasma processing relative to the substrate (10) may increase in proportion to a reciprocating frequency of the plasma source (200).

The plasma source (200) may include an antenna coil (210) connected to an RF power source, and a mover (230) configured to translate the antenna coil (210). The antenna coil (210) may have a variable configuration arranged in parallel to the substrate (10). In other words, when the substrate (10) is placed on a xy plane, the antenna coil (210) may be also arranged on the xy plane in various shapes. For example, when the mover (230) moves to a first direction, the antenna coil (210) may be extended to a second direction different from the first direction. A plurality of antenna coils (210) extended along the y axis is connected in parallel to the RF power source in the drawing.

The antenna coil (210) may be uniformly applied with an average voltage along a direction distanced from the mover (230), with the mover (230) as a starting point.

FIG. 2 illustrates an antenna coil (210) bent in a ‘U’ shape, with a starting portion and an ending portion being mutually adjacent. When an RF input voltage V=1 is applied at an Ain point connected to the mover, a voltage drop occurs, whereby V=0 at an Aout, which is a power source grounded point.

Furthermore, when a voltage is ¼ applied to one strand in a branch coil formed with two strands, a voltage applied to the other strand is ¾, and an average voltage, which is a sum of the voltages, becomes 1. Still furthermore, voltage at each strand at outermost portions of the branch coil is ½ and therefore an average voltage becomes 1. That is, in terms of substrate (10) positioned at underneath the antenna coil (210), the substrate (10) receives an effect in which an average voltage V=1 is applied along the antenna coil (210), whereby a voltage difference generated in the antenna structure can be minimized. This is because the antenna coil (210) has a ‘U’ shaped coil structure.

Two antenna coils (210) may form a pair, where a distal end of each antenna coil (210) may be connected in parallel. The other distal end of one of the two antenna coils (210) may connected to the RF power source, and the other distal end of the another of the two antenna coils (210) may be grounded.

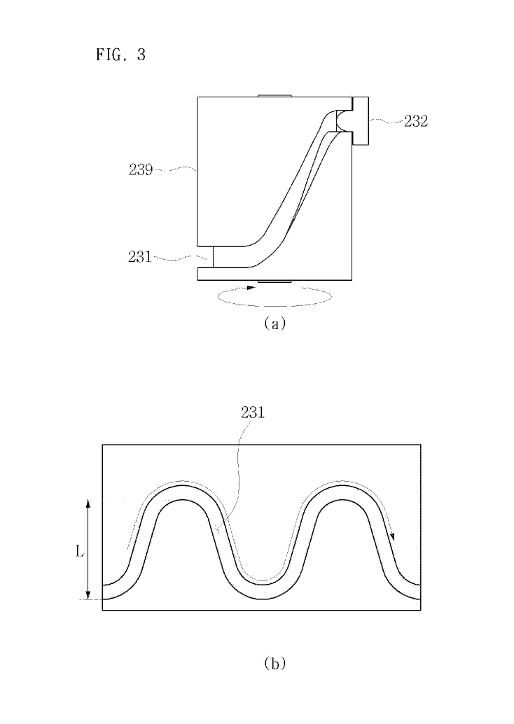

The mover (230) may move in parallel relative to the substrate (10) whereby the antenna coils (210) connected to the mover (230) are made to translate. The mover (230) may be connected with the RF power source via a flexible wire, whereby the antenna coils (210) may receive the RF power source by being electrically connected to the mover (230). FIG. 3 illustrates the mover (230) translating along the x axis direction.

The substrate (10) is preferable to take a shape extended along a direction of translating motion (x axis direction) in order to uniformly plasma-process the substrate (10) through the translating motion. For example, the substrate (10) may take a rectangular shape. The mover (230) may translate in various methods. For example, the mover (230) may include a ball screw or a cam configured to transform the rotational motion of a motor (238) to a direction motion. The translation of the mover (230) may be accomplished by inserting a ball in a groove provided at a screw extended to the x axis direction and moving the mover (230) along with the relevant ball. Of course, the motor (238) rotating the screw periodically repeats the forward and backward rotations.

In order to increase a driving efficiency of the motor (238), the motor (238) may be configured to rotate only to one direction. In this case, a cam may be used instead of ball screw.

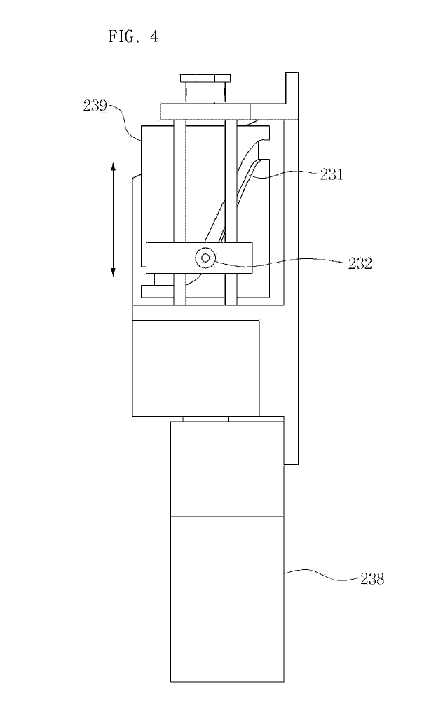

FIG. 3 is a schematic view illustrating a cam part (239) forming a plasma device according to the present disclosure, and FIG. 4 is a schematic view illustrating the mover (230) applied with the cam part (239).

FIG. 3 (a) illustrates a front view of the cam part (239) and FIG. 3(b) illustrates an imaginary view in which the cam part (239) is unfolded. The cam part (239) may take a cylindrical shape externally formed with a first guide (231) in a graph shape of periodic function. The first guide (231) may be a groove or a lug. FIG. 3 illustrates the first guide (231) in a shape of a groove.

When the cam part (239) rotates clockwise as in FIG. 3(a), the second guide (232) meshed to the first guide (231) may move to an arrow direction along the first guide (231) as in FIG. 3(b). The second guide (232) rotated to one direction by the cam part (239) may reciprocate along an extended direction of the cam part (239). To be more specific, the second guide (232) may reciprocate in an L section which is a length twice the amplitude of a graph shown by the first guide (231).

When the antenna coil (210) is connected to the cam part (239) or the antenna coil (210) is connected to the second guide (232) moving along the first guide (231), the antenna coil (210) translates. For example, it is assumed that the antenna coil (231) is fixed to the second guide (232). The cam part (239) is rotated to a predetermined direction as a link provided between the motor (238) and the cam part (239) is driven by the rotation of the motor (238) in FIG. 4. At this time, the second guide (232) may move along the first guide (231) formed at the cam part (239) and the antenna coil (210) may reciprocate in the L section to allow the translation relative to the substrate (10).

At this time, however, there is generated a speed reduction at a valley part of the graph by the abovementioned cam part (239), whereby the antenna coil (210) slows down in speed at a marginal section over the translation at an intermediate section. As a result, a large amount of plasma may be applied to a margin of the substrate.

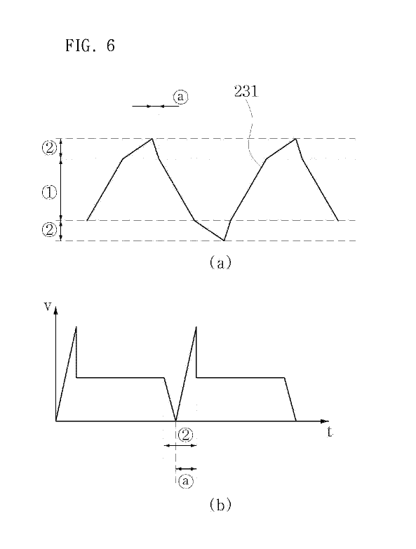

FIG. 6 is a schematic view illustrating another cam part forming a plasma device according to the present disclosure.

Referring to FIG. 6(a), the first guide (231) may be formed a first section \textcircled{1} to allow the second guide (232) to cruise, and a second section \textcircled{2} extended from the first section \textcircled{1} to reduce the speed of the second guide (232), where the second section \textcircled{2} may include an acceleration section \textcircled{a} in which the second guide (232) accelerates after finish of the speed reduction. At this time, the speed of the second guide (232) at the acceleration section \textcircled{a} is faster than the second guide (232) at the first section \textcircled{1}. To this end, the first guide (231) may be so formed as to allow an absolute value of an incline at the acceleration section \textcircled{a} is greater than an absolute value of an incline at the first section \textcircled{1}.

Although a greater amount of plasma is applied to the substrate (10) at the second section \textcircled{2} than at the first section \textcircled{1} due to speed reduction of the antenna coil (210) at the second section \textcircled{2}, the antenna coil (210) moves at a faster speed at the re-accelerated acceleration section \textcircled{a} after finish of speed reduction at the second section \textcircled{2} than at the first section \textcircled{2}, whereby a smaller amount of plasma is applied to the substrate (10) over the first section \textcircled{1}. Thus, an amount of plasma generated at the second section \textcircled{2} is equal to that of the first section \textcircled{1}. As a result, the substrate can be uniformly plasma-processed. FIG. 6(b) illustrates a speed change at the second guide (232) in response to time.

A ball screw and a cam may be provided at the same time. The ball screw may be connected to the motor to be rotated along with a shaft of the motor. It is preferable that the ball screw or the motor rotate to any one direction of forward direction and backward direction for efficiency sake. At least any one of the ball screw and the cam may be formed with the first guide (231) to allow the ball screw rotating to one direction to have a trajectory moving to the other direction after moving to one direction of a lengthwise direction of the ball screw.

The first guide (231) may transform the rotating motion of the motor and the ball screw to a direct motion of can. When the cam is connected to the antenna coil (210), the antenna coil (210) may reciprocate to one direction and to the other direction of a lengthwise direction of the ball screw.

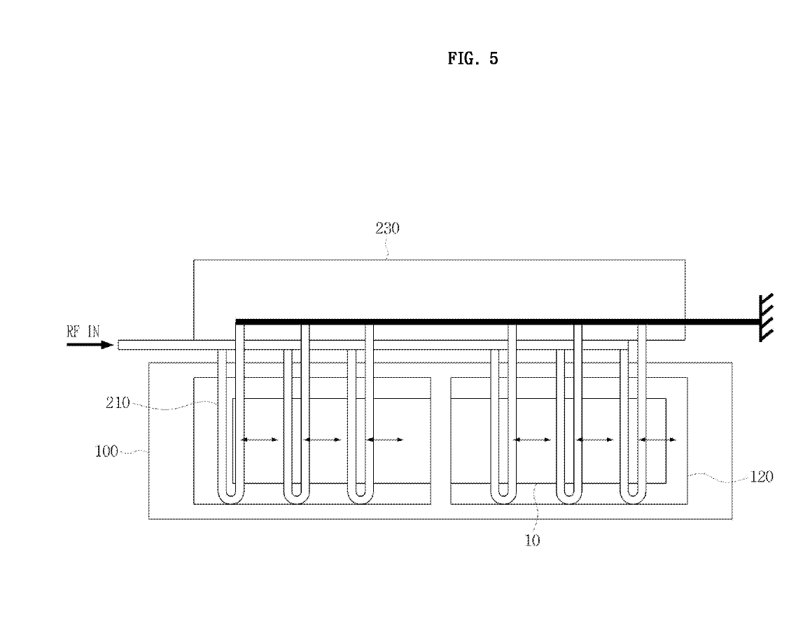

FIG. 5 is a schematic view illustrating another plasma device according to the present disclosure.

FIG. 5 illustrates a chamber (100) provided with a plurality of covers (120). At this time, the plasma source (200) may include an antenna coil group provided to correspond to each cover (120). The each antenna coil group may be connected to one mover (230). As a result, one mover (230) can perform the plasma processing on the chamber (100) provided with the plurality of covers (120) or on the plurality of chambers (100).

For example, when a long substrate is plasma-processed, a length of the cover (120) may be lengthened in response to the long substrate. However, when the length of the cover (120) is lengthened in length, the cover (120) may be damaged due to its characteristics. Thus, a plurality of covers may be formed. When it is assumed that a set of antenna coils taking charge of each cover (120) is an antenna coil group, all antenna coil groups may translate altogether by installing each antenna coil group to one mover (213).

To wrap up, when the plasma source (200) includes an antenna coil (210) connected to the RF power source, and a mover (230) configured to translate the antenna coil (210), a plurality of covers (120) may be arranged between the chamber (100) and the antenna coil (210). Furthermore, when the antenna coil (210) moves in parallel to a first direction, each cover (120) may be arranged along the first direction, whereby a lengthy substrate (10) can be plasma-processed without damage to the cover (120).

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims

What is claimed is:

1. A plasma device, the plasma device comprising:
a chamber configured to accommodate a substrate; and
a plasma source formed at one side of the chamber to excite a reaction gas of the substrate introduced into the chamber in a plasma state, wherein the plasma source moves in parallel with the substrate.

2. The plasma device of claim 1, wherein the plasma source moves to a wire or to a belt.

3. The plasma device of claim 1, wherein the plasma source includes an antenna coil connected to an RF power source, and a mover configured to translate the antenna coil, and the mover includes a ball screw or a cam configured to transform a rotational motion of a motor to a translational motion.

4. The plasma device of claim 1, wherein the plasma source includes an antenna coil connected to an RF power source, and a mover configured to translate the antenna coil, wherein the mover includes a ball screw or a cam configured to transform a rotational motion of a motor to a translational motion, and wherein the ball screw is connected to the motor, and the motor and the ball screw are rotated to one direction of a forward direction or a backward direction, and wherein at least one of the ball screw and the cam is formed with the motor rotating to the said one direction and a first guide configured to transform a rotational motion of the ball screw to a direct motion of the cam, and wherein the first guide is formed with a trajectory configured to move the cam to the other direction of the ball screw after moving the cam to one direction of the ball screw.

5. The plasma device of claim 1, wherein the plasma source includes an antenna coil connected to an RF power source, and a mover configured to translate the antenna coil, wherein the mover includes a cam part, and wherein the cam part takes a cylindrical shape externally formed with a first guide in a graph shape of periodic function, and wherein the antenna coil is connected to the cam part or to a second guide moving along the first guide.

6. Plasma device of claim 5, wherein the first guide includes a first section to allow the second guide to cruise, and a second section extended from the first section to reduce speed, and wherein the second section includes an acceleration section in which the second guide accelerates after finish of the speed reduction, and wherein the speed of the second guide at the acceleration section is faster than the second guide at the first section.

7. Plasma device of claim 1, wherein the plasma source includes an antenna coil connected to an RF power source, and a mover configured to translate the antenna coil, wherein a plurality of covers is arranged between the chamber and the antenna coil, and wherein each cover is arranged along a first direction when the antenna coil moves in parallel to the first direction.

8. The plasma device of claim 1, wherein the plasma source includes an antenna coil connected to an RF power source, and a mover configured to translate the antenna coil, wherein the mover moves along the first direction and the antenna coil is extended to a second direction which is different from the first direction.

9. The plasma device of claim 8, wherein the antenna coil is formed with a U-shape to allow an average voltage to be constantly applied along a direction distancing from the mover with the mover as a starting point.
